(19) United States
(12) Patent Application Publication
(10) Pub. No.: US 2026/0251728 A1
(43) Pub. Date: Aug. 27, 2026

(54) TEST DEVICE AND METHOD FOR TESTING A HIGH-VOLTAGE OR MEDIUM-VOLTAGE CABLE AND METHOD FOR TESTING A TRANSFORMER ARRANGED IN A TEST DEVICE

(71) Applicant: b2 electronics GmbH, Klaus (AT)

(72) Inventors: Christian MATHIES, Bartholomaeberg (AT); Michael FRICK, Rankweil (AT)

(73) Assignee: b2 electronics GmbH, Klaus (AT)

(21) Appl. No.: 19/649,797

(22) Filed: Apr. 16, 2026

Related U.S. Application Data
(63) Continuation of application No. PCT/EP2024/078943, filed on Oct. 15, 2024.

(30) Foreign Application Priority Data
Oct. 17, 2023 (DE) 10 2023 128 396.0

(51) Int. Cl. G01R 31/58; G01R 31/52; G01R 31/62

(52) U.S. Cl. CPC G01R 31/58; G01R 31/52; G01R 31/62

(57) ABSTRACT

A test device for testing a test object, such as a high-voltage or medium-voltage cable, includes a power converter, a transformer for transforming an HF signal into a high-voltage signal, wherein the transformer comprises a primary winding, a protective earth shield for shielding the primary winding, wherein the protective earth shield is capacitively coupled to the primary winding and is electrically connected to the protective earth potential, a secondary winding, and an internal earth shield for shielding the secondary winding, wherein the internal earth shield is capacitively coupled to the secondary winding and is electrically connected to the internal earth collection point. The test device further comprises a rectifier circuit electrically connected to the high-voltage output for outputting a rectified high-voltage signal and a high-voltage circuit arrangement for generating the VLF test voltage based on the rectified high-voltage signal.

### CROSS REFERENCE TO RELATED APPLICATIONS

This application is a continuation under 35 U.S.C. §120 of International Application PCT/EP2024/078943, filed October 15, 2024, which claims priority to German Application No. 10 2023 128 396.0, filed October 17, 2023, the contents of each of which are incorporated by reference herein in their entirety.

### FIELD OF THE INVENTION

The present invention relates to a test device for testing a test object (for example, a high-voltage or medium-voltage cable), in particular for testing insulations in, for example, coaxial cables for the distribution of current/energy in electrical supply networks by means of VLF testing methods. The invention further relates to a method for testing a transformer in such a test device.

### BACKGROUND

The testing of high-voltage or medium-voltage cables, for example, cables laid in the ground or running through water in the context of regional energy networks, comprises the testing for the purpose of determining possibly existing defects or pre-damages, which can form, for example, at the insulation of a high-voltage cable. Exemplary defects further comprise defects in the cable insulation, such as water trees or electrical trees, which do not yet produce a breakthrough or produce a breakthrough during the VLF testing. High-voltage or medium-voltage cables (also referred to herein as a test object or device under test (DUT)) are generally cables, which are designed for the distribution of energy/power using voltages in the high-voltage and medium-voltage range beginning at approximately 1 kV up to a few hundred kV (and more), for example, in power networks for the electrical energy supply. The distribution of energy/power can take place, for example, over distances from a few hundred meters up to a few ten kilometers (at up to more than 1 GW of power and up to 500 kV of voltage).

With regard to the presence of a pre-damage, mobile VLF test devices make it possible to test a test object with the aid of a test voltage, for example, in the range from 20 kVpeak to 120 kVpeak (generally not limited), which is produced with a highly precise sinusoidal voltage profile at a frequency in the range from 0.01 Hz to 1 Hz, the so-called very low frequency (VLF), and is applied to the test object as an energy cable at the conductor with respect to protective earth potential (Protective Earth PE). VLF-based testing methods are known and defined, for example, in IEEE 400.2. What is essential for VLF-based testing methods is a measurement of a test current being as free as pssobiel from disturbancds, where the test current follows the voltage profile of the kV test voltage produced.

For the voltage production, VLF test devices comprise special VLF high-voltage sources (also referred to as VLF high-voltage source/sources). A VLF high-voltage source can preferably comprise two high-voltage sources (transformers with a cascade circuit) and an output amplifier (in the form of current sources) that together produce a highly undisturbed, sinusoidal output voltage (the “test voltage”). Circuit arrangements for the production of such test voltages are disclosed, for example, in DE 10 2012 024 560 B3 of the applicant or DE 195 13 441 A1.

For a diagnosis with regard to the presence of a pre-damage (e.g., water tree), a loss factor can be determined in a so-called tangent delta measurement. For a tangent delta measurement — despite the connection of the test object to protective earth — the current through the DUTs having the defect can be detected, i.e., without the test object having to be separated from the protective earth. For example, a current detection element (e.g., impedance as a current shunt) for a tangent delta measurement can be provided internally in a VLF test generator with which the current and the phase through the test object, in particular between protective earth potential and internal earth potential, can be measured/detected at a so-called internal earth collection point, also referred to herein as a current collection point. In other words, the current collection point is selected in the VLF test generator such that the current flows through the current collection point from the test object back to the high-voltage cascade. For example, DE 10 2012 024 560 B3 discloses an advantageous arrangement for a highly accurate diagnostic measurement in which a highly accurate test current can be produced and measured with the aid of a central clock signal and a sinusoidal envelope curve of a test voltage. The test current is detected, for example, with a resistance in the range of 0.01 kΩ to 1 kΩ with a sampling rate in the range of 5 kHz to 100 kHz and is used to determine the power loss (resistive leakage current) via the phase shift, for example, by means of Fourier transformation (e.g., discrete Fourier transformation (DFT)).

As is also disclosed in DE 10 2012 024 560 B3, an increased quality of the test voltage leads to an improvement in the tangent delta measurability. However, as the power of a VLF test generator increases, the disturbance signals at the current collection point also increase, in particular when a non-potential-isolated intermediate circuit generation is used to convert an input alternating voltage into an HF signal with respect to a floating reference potential. In the latter case, the necessary potential isolation usually takes place during the generation of the high voltage with transformers (HV transformers) for the cascade circuit(s). For details in this regard, see also the following description.

One aspect of this disclosure is based on the object of providing a device and a method for a tangent delta measurement in which disturbances on the test current through the test object, the test current being used for the measurement, are reduced (the disturbances being in particular a parasitic current due to harmonics of the mains voltage and/or a leakage current of a transformer).

A further aspect of this disclosure is based on the object of providing a compact and cost-effective setup of a test device for testing a high-voltage or medium-voltage cable, which test device enables safe, simple and cost-effective test methods to be carried out.

### SUMMARY

At least one of these objects may be achieved by a test device for testing a test object, in particular a high-voltage or medium-voltage cable.

In an aspect, a test device for testing a test object, e.g., a high-voltage or medium-voltage cable, with a test method using a very low-frequency (VLF) test voltage comprises a power converter. The power converter comprises an alternating voltage input for receiving an input alternating voltage with respect to a protective earth potential, a low-voltage circuit arrangement comprising a rectifier circuit and at least one switching power supply, wherein the low-voltage circuit arrangement is configured to generate an HF signal with respect to a floating reference potential from the input alternating voltage, and at least one HF output pair for outputting the HF signal and the floating reference potential. The test device further comprises a transformer for transforming the HF signal into a high-voltage signal. The transformer comprises a primary winding, the winding ends of which are electrically connected to the HF output pair, a protective earth shield for shielding the primary winding, wherein the protective earth shield is capacitively coupled to the primary winding and is electrically connected to the protective earth potential, a secondary winding, the first winding end of which is electrically connected to an internal earth collection point and the second winding end of which is electrically connected to a high-voltage output for outputting the high-voltage signal, and an internal earth shield for shielding the secondary winding, wherein the internal earth shield is capacitively coupled to the secondary winding and is electrically connected to the internal earth collection point. The test device further comprises a rectifier circuit electrically connected to the high-voltage output for outputting a rectified high-voltage signal, and a high-voltage circuit arrangement for generating the VLF test voltage based on the rectified high-voltage signal.

In a further aspect, a method for testing a test object, e.g., a high-voltage or medium-voltage cable, using such a test device comprises the following steps:

producing a test voltage with the test device,

causing a measurement current with the test voltage when the high-voltage or medium-voltage cable is connected in a connecting conductor, which electrically connects an internal earth collection point of the test device to a protective earth connection of the test device, so that the test current flows through the connecting conductor when the test object (e.g., the high-voltage or medium-voltage cable) is tested, said measurement current being formed between the internal earth collection point and a shield of the test object (e.g., the high-voltage or medium-voltage cable), said shield likewise being at protective earth potential,

producing a low-frequency diagnostic signal assigned to the measurement current for a VLF phase rotation measurement with a low-frequency signal tap on the connecting conductor, and

evaluating the low-frequency diagnostic signal in evaluation electronics with regard to a fault in the high-voltage or medium-voltage cable.

In a further aspect, a method for testing a transformer arranged in such a test device, wherein an internal earth shield of the secondary winding of the transformer is electrically connected to an internal earth collection point of the test device via a leakage current measurement impedance, comprises the following steps:

producing a test voltage with the test device,

measuring a leakage current with the leakage current measurement impedance, and

evaluating the leakage current in evaluation electronics of the test device with regard to an insulation damage of the transformer.

In some embodiments of the test device, an intermediate circuit for generating a direct voltage with respect to the floating reference potential can be formed in the low-voltage circuit arrangement, wherein the direct voltage is subjected to harmonics depending on the received input alternating voltage, and the protective earth shield capacitively coupled to the primary winding is configured to discharge a parasitic current caused by the harmonics to the protective earth potential.

In some embodiments of the test device, the internal earth shield capacitively coupled to the secondary winding can be configured to discharge an HF high-voltage leakage current produced in the transformer to the internal earth collection point.

In some embodiments of the test device, the transformer can further comprise a transformer core, which is configured as part of the internal earth shield capacitively coupled to the secondary winding and is electrically connected to the internal earth collection point.

In some embodiments of the test device, the transformer can further comprise a winding body, in particular U-shaped in cross-section, on which the primary winding is arranged embedded in the protective earth shield, an insulating film, the internal earth shield and the secondary winding, and wherein the winding body can be arranged in particular between sections of a core of the transformer and/or wherein the primary winding can be delimited radially on both sides by the protective earth shield and/or the secondary winding can be delimited radially on both sides by the internal earth shield.

In some embodiments of the test device, the power converter and the transformer can form a high-voltage source and the high-voltage circuit arrangement can comprise at least one semiconductor switch cascade and at least one amplifier, which are assigned to the transformer.

In some embodiments of the test device, the low-voltage circuit arrangement can comprise two switching power supplies, which are configured such that a positive and a negative HF signal are output at corresponding HF output pairs. Furthermore, the test device can comprise two transformers, each comprising a protective earth shield and an internal earth shield, for transforming the positive and the negative HF signal into a positive and a negative high-voltage signal and two rectifier circuits electrically connected to high-voltage outputs of the transformers for outputting a rectified positive and a rectified negative high-voltage signal. In particular, the high-voltage circuit arrangement can be configured for generating the VLF test voltage based on the positive rectified high-voltage signal and the negative rectified high-voltage signal.

In some embodiments of the test device, the high-voltage circuit arrangement can comprise a test object connection for connecting a high-voltage-side output of the high-voltage circuit arrangement to a conductor of the test object (e.g., of the high-voltage or medium-voltage cable), in particular via a measurement connection cable.

In some embodiments of the test device, the test device can further comprise a protective earth connection, a connecting conductor, which electrically connects the internal earth collection point to the protective earth connection, so that a measurement current flows through the connecting conductor when the test object (e.g., the high-voltage or medium-voltage cable) is tested, said measurement current being formed between the internal earth collection point and a shield of the test object (e.g., the high-voltage or medium-voltage cable), said shield likewise being at protective earth potential, a low-frequency signal tap on the current collection point, at which a low-frequency diagnostic signal is produced based on the measurement current, and evaluation electronics, which are connected to the low-frequency signal tap for receiving the low-frequency diagnostic signal and are configured for a VLF phase rotation measurement.

In some embodiments of the test device, the low-frequency signal tap can be configured to detect an instantaneous value of a current strength in the connecting conductor, and/or comprises an impedance in the connecting conductor, in particular a parallel circuit of resistor and capacitor. Additionally or alternatively, the evaluation electronics can be configured to determine a loss factor assigned to the high-voltage or medium-voltage cable from the diagnostic signal. In particular, it can be designed for detecting low frequencies of the diagnostic signal in the range of 0.01 Hz to 1 Hz with a sampling rate with frequencies in the range of, in particular, 5 kHz to 100 kHz. Additionally or alternatively, the evaluation electronics can comprise at least one analog and/or digital signal processing unit and/or a processor and/or a buffer memory.

In some embodiments, the test device can comprise a signal tap, in particular a leakage current measurement impedance or a leakage current measurement resistor, which electrically connects the internal earth shield of the secondary winding of the transformer to the internal earth collection point and is provided for detecting a structural fault of an insulation of the transformer.

In some embodiments of the method for testing a test object (e.g., high-voltage or medium-voltage cable), a parasitic current caused by harmonics of a received input alternating voltage can be discharged to the protective earth potential via a protective earth shield. Additionally or alternatively, a leakage current produced in the transformer can be discharged to the internal earth collection point via an internal earth shield of the transformer.

The concepts described herein can have, inter alia, the following advantages over the prior art or avoid corresponding disadvantages of the prior art:

One source of disturbances — in particular in the case of a tangent delta measurement — is the input alternating voltage used (e.g., mains input voltage) and its multiplication (two times and multiple times) in the amplification path. For example, currents can be attributed to an (input bridge) rectifier in the power converter (wherein the rectifier is embodied, e.g., as a “power factor corrector” or “power factor correction filter”), even if the rectifier itself is coupled to protective earth via capacitors (EMC/EMC). The power converter usually generates an HF signal with respect to a floating reference potential from the input alternating voltage using an intermediate circuit, wherein the HF signal is also referred to as a “floating power ground” (PGND). Disturbances resulting from the non-potential-isolated intermediate circuit voltage can be capacitively coupled to the transformation and thus transmitted to the current measurement. As a result, for non-potential-isolated structures, frequency components, which are attributed to the input alternating voltage, can propagate to the measurement signal.

Furthermore, when a current collection point is used for an integrated tangent delta measurement, leakage currents can occur within the transformers due to the high voltage, wherein the leakage currents are to be considered as possible disturbance variables in the measurement.

The inventors have recognized that the use of a filter with a corresponding bandwidth to remove such disturbance signals can also trim the useful signal and lead to a phase shift, whereby the tangent delta measurement would also be influenced. Moreover, it has been recognized that a filter cannot or cam only to a limited extent compensate for fluctuations (e.g., caused by generator operation and/or 50/60 Hz networks) in the frequency at the network input.

In contrast thereto, the concept proposed by the inventors of equipping transformers with a “double” shield does not change the useful signal. Rather, as explained below, frequency components attributed to the input alternating voltage can be discharged to protective earth and capacitively coupled leakage currents of the transformer can be discharged directly to internal earth.

In particular, the inventors have recognized that when a shield of the primary winding of a transformer, also referred to herein as protective earth shield, is connected to protective earth, parasitic currents can be avoided by the test object or can be passed by the tangent delta measurement. In other words, parasitic currents attributed to the input alternating voltage are returned to the source by introducing a shield of the primary winding lying on protective earth. This protective earth shield returns the parasitic currents attributed to the input alternating voltage to the source.

The “double” shield configuration further comprises a shield of the secondary winding of the transformer, also referred to herein as internal earth shield. This shield is electrically connected to the internal earth collection point, whereby leakage currents on the secondary side of the transformer can be passed by the measurement. In other words, leakage currents are coupled directly to the current collection point.

By introducing the protective earth shield and the internal earth shield, a sensitive tangent delta measurement can be enabled. In general, the concepts proposed herein can achieve a further improvement in the accuracy of integrated diagnostic measurements (such as a tangent delta measurement). Furthermore, they can also improve an external diagnostic measurement (such as a partial discharge measurement).

Advantages of the concepts proposed herein are manifested in particular in the case of large test currents (load capacitances), i.e., in the case of higher powers and higher applied voltages. In particular, VLF test generators in power classes from approximately 500 W output power and test voltages from, e.g., 45 kV can be used owing to the concepts proposed herein for the “low-harmonics” measurement method described above (see also DE 10 2012 024 560 B3). In the case of powers in the range from, for example, 1 kW to 4 kW, a greater influence can moreover also be avoidable if such a high power is requested.

### BRIEF DESCRIPTION OF THE DRAWING

Concepts are disclosed herein that allow aspects from the prior art to be improved at least in part. In particular, further features and their usefulnesses result from the following description of embodiments with reference to the figures. Of the figures:

FIG. 1 shows a schematic illustration of an exemplary test device for testing a high-voltage or medium-voltage cable in accordance with the inventive concept;

FIG. 2 shows a schematic circuit diagram of an exemplary setup of a circuit arrangement in a test device, e.g., in accordance with FIG. 1;

FIG. 3 shows a flow diagram of an exemplary sequence of a test of a high-voltage or medium-voltage cable;

FIG. 4 shows a schematic illustration of an exemplary setup of a transformer for use, e.g., in a circuit arrangement as shown in FIG. 2 in a test device for testing a high-voltage or medium-voltage cable;

FIGS. 5 and 6 show plots of a VLF test voltage, produced without a “double” shield configuration (FIG. 5) and produced with a “double” shield configuration (FIG. 6), for illustrating the disturbance reduction; and

FIGS. 7 and 8 show plots of frequency spectra of produced VLF test voltages, produced without a “double” shield configuration (FIG. 7) and produced with a “double” shield configuration (FIG. 8), for illustrating the disturbance reduction.

### DETAILED DESCRIPTION OF THE PREFERRED EMBODIMENTS

The invention relates in particular to the implementation of a tangent delta measurement in the context of a non-potential-isolated structure of a VLF test device while avoiding AC disturbance signals and transformer leakage currents, whereby a test of a test object/high-voltage or medium-voltage cable can be carried out in a highly resolved and highly sensitive manner in context of the tangent delta diagnosis.

The inventors propose herein a concept of the double shielding of (high-power) transformers used in a test device for testing a high-voltage or medium-voltage cable, which can be used instead of, for example, a complete potential isolation that is complex in terms of circuitry, is afflicted with power loss and is expensive in the implementation — either on the input side, in the DC intermediate circuit, between H bridges and HV transformers or in the high-voltage path.

According to embodiments of the invention, a feedback of disturbance signals, which are attributed to the input alternating voltage, e.g., network ripple, to protective earth potential takes place, wherein at the same time a discharge of a VLF leakage current to an internal earth potential is performed. In this way, a disturbance signal coupled via the PGND is passed by the test object and does not add to the current measurement. The feedback of the disturbance signal can take place by a shield (shield winding) surrounding the primary winding — here a circumferential shield, but forming no short-circuit winding. For example, the formation of, e.g., a 100 Hz ripple at a 50 Hz input alternating voltage on the measurement signal for the tangent delta diagnosis can be avoided.

However, leakage currents in the transformers used for high-voltage generation can lie on the measurement signal for the tangent delta diagnosis. An internal earth shield introduced according to embodiments of the invention, which shields the secondary winding, can discharge such leakage currents in a controlled manner to the current collection point. In a simple structural setup, a (e.g., ferrite) core of the transformer can be used as part of the internal earth shield and correspondingly can be electrically connected to the internal earth potential.

Furthermore, the internal earth shield of the double shield setup according to embodiments of the invention can be used for the testing of the transformers. For example, a leakage current in the transformer, which was caused, e.g., by a faulty insulation in the transformer, can be detected via a second measurement shunt (measurement impedance/measurement resistor between the shield of the secondary coil shield and the internal earth collection point). Thus, using the double shield, the functionality of the transformers of the VLF test device can be monitored during operation.

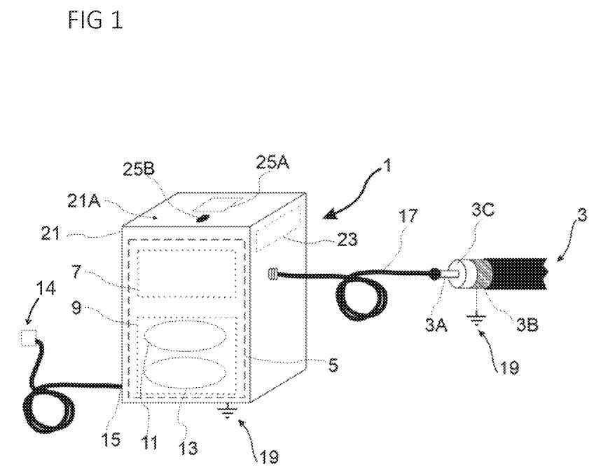

FIG. 1 shows a schematic illustration of a portable test device 1 for testing a test object 3, e.g., a schematically illustrated high-voltage or medium-voltage cable, such as a coaxial cable, in accordance with the inventive concept. The test device 1 comprises a circuit arrangement 5, essentially a VLF test voltage generation unit 7 for generating a suitable (VLF) test voltage, and (measurement and) evaluation electronics 9 coupled to the circuit arrangement 5 and integrated into the test device. The evaluation electronics 9 is configured, e.g., for a tangent delta measurement (tangent delta measurement unit 11) and optionally for a transformer monitoring (transformer monitoring unit 13). The hardware (computation unit) on which the evaluation electronics 9 is based has, for example, digital processor systems with microprocessor circuits having data inputs and control outputs, which are operated in accordance with computer-readable instructions stored on a computer-readable medium. The evaluation electronics 9 usually comprise a high computing power for a real-time analysis of the continuously detected and to be evaluated data sets as well as long-term (non-volatile) memories for storing the program instructions as well as very fast short-term (volatile) memories for storing acquired data and evaluation results during (or resulting from) the data acquisition and the data processing of low-frequency and/or high-frequency signals.

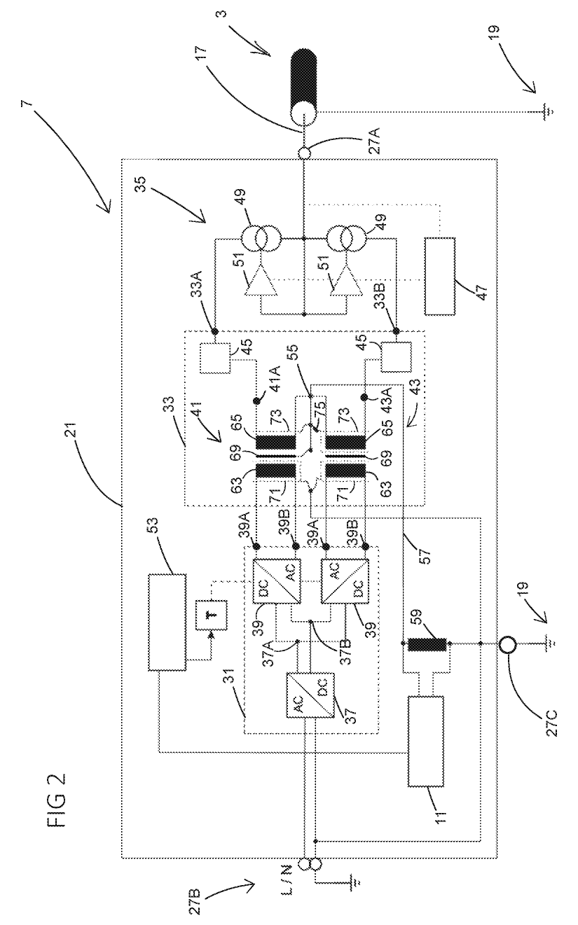

The test device 1 is supplied with energy (power connection 15) via, for example, the power network as source 14 (generally a supply voltage source for outputting an input alternating voltage to the test device 1, e.g., a 50 Hz/60 Hz power network or a regulated generator with adjustable frequencies in the range of, e.g., 40 Hz to 65 Hz). For the test, a conductor 3 A of the test object 3 is connected to the test device 1 via an (HV) connection cable 17 (with exemplary lengths of 5 m to 15 m). A shield 3 B of the test object 3 and the circuit arrangement 5 are connected to a protective earth potential 19. The power connection 15 can also comprise a line lying on protective earth (see, e.g., FIG. 2). A to be tested insulation 3C of the test object 3 lies between the conductor 3A of the test object 3 and the shield 3B.

The circuit arrangement 5 is arranged in a housing 21 of the test device 1 and can comprise electronic components such as a signal processing with operational amplifiers, at least one integrator, a sample and hold element, at least one analog-digital converter for digitization for the further processing in a processor, which has at least one memory for storing sampling data (measurement data). The circuit arrangement 5 can further be connected to a control 23 of the test device 1, which is provided in the test device 1 or provided completely or partially outside the test device 1 or which can be (partially) integrated into the control 23. The control 23 and the high-voltage sources included in the circuit arrangement 5 together generate the test voltage to be applied to the test object 3 in that, e.g., via transformers and downstream cascade multipliers, the control 23 provides and controls the power for the current sources, which are required for regulating the test voltage, see FIG. 2 for an exemplary circuit arrangement.

In FIG. 1, an operating display 25A (display) for displaying the obtained test data and at least one operating element 25B for setting a measurement parameter are schematically indicated exemplarily on an upper side 21A of the housing 21. The operating display 25A and the operating element 25B form, for example, a user interface of the control 23.

FIG. 2 shows an exemplary circuit diagram for the components of the circuit arrangement 5 of the test device 1 illustrated in FIG. 1, the components being provided in the housing 21. The test object 3 is connected to a test object connection 27 A, which is provided, for example, on the housing 21, via the connection cable 17 and is further electrically connected to the protective earth potential 19 on the shield. In order to supply the circuit arrangement 5 with an input alternating voltage, the test device 1 is connected to the supply voltage source 14 (see FIG. 1) at a power connection 27B, which is provided, for example, on the housing 21. The power connection 27B comprises, e.g., a voltage-carrying, a neutral, and a grounded connection. FIG. 2 further optionally shows a protective earth connection 27C, which is provided, for example, separately on the housing 21, for sufficient grounding of the housing 21 and for coupling the protective earth with low impedance to the DUT (e.g., for a tangent delta measurement).

The circuit arrangement comprises a power converter 31, two transformers with cascade circuits (combined in boxes 33 in FIG. 2) as high-voltage sources, and a high-voltage circuit arrangement 35.

The power converter 31 is supplied with energy via the power connection 27B and comprises a rectifier circuit 37 (AC/DC converter), which generates a direct voltage (of regulated amplitude) from the input alternating voltage. The power converter 31 further comprises two switching power supplies 39 (DC/AC converters) electrically connected inversely to direct voltage outputs 37A, 37B of the rectifier circuit 37. The rectifier circuit 37 and the switching power supplies 39 represent herein an example of a low-voltage circuit arrangement, which generates two inverse HF signals for the two high-voltage sources 33 starting from the input alternating voltage at two pairs of HF outputs 39A, 39B of the switching power supplies 39.

The sketched, non-potential-isolated design of the power converter 31 relates, in particular, to VLF test generators for higher powers/higher voltages, which use a power factor corrector (PFC) on the mains input side in order to rectify an alternating voltage provided by the mains (or by another source such as mobile generators) and to provide a DC voltage for further amplification. The output voltage for the power range of 1 kW to 4 kW is, for example, 400 V. A voltage reference point of the output DC voltage is not at protective earth potential due to the lack of potential isolation, but rather represents a PGND, having a potential resulting with respect to protective earth potential from the circuit of the rectifier at half the input voltage. Due to the technically induced capacitive coupling, the PGND can have a ripple of twice or multiple the input frequency, whereby that ripple — not addressed — can lead to corresponding effects on the measurement.

The high-voltage sources 33 are configured to provide a positive (+) or negative (−) high voltage of variable amplitude at their respective outputs 33A, 33B, in that, for example, a modulation is operated with a multiple of the mains frequency. The high-voltage sources 33 each comprise a (high-voltage) transformer 41, 43 for transforming the HF signal into a high-voltage signal respectively present at a high-voltage output 41A, 43A of the respective transformer 41, 43. For example, amplifications are present starting from, for example, 400 V (at the HF output pair) to, e.g., 13 kV (at the high-voltage output 41A, 43A). The high-voltage sources 33 further each comprise a rectifier circuit 45 electrically connected to the high-voltage output 41A, 43A for outputting a rectified high-voltage signal at the outputs 33A, 33B of the high-voltage sources 33.

The high-voltage circuit arrangement 35 is provided between the outputs 33A, 33B of the high-voltage sources 33 and the test object 3. The high-voltage circuit arrangement 35 is configured for shaping the VLF test voltage based on the rectified high-voltage signal. The high-voltage circuit arrangement 35 is acted on by means of a control unit 47 for defined charging and discharging of the test object 3 that represents a certain capacitive load. The control unit 47 is configured to ensure a, preferably sinusoidal, voltage profile at the test object 3. In the embodiment shown by way of example in FIG. 2, the high-voltage switch arrangement 35 comprises, e.g., semiconductor switch cascades 49 and amplifiers 51, on which the control unit 47 acts.

Furthermore, the switching power supplies 39 of the low-voltage circuit arrangement are driven by a controller 53 with the aid of a clock signal generator T, so that the two switching power supplies 39 in combination with the high-voltage sources 33 can each provide a test voltage that is synchronized using the clock signal generator T, can be predefined in a defined manner in curve form and amplitude, is advantageously edge-free and in particular sinusoidal, and in particular is not influenced by the control unit 47.

For further details for the generation and regulation of the test voltage and further alternative embodiments of the circuit arrangement, reference is made, by way of example, to DE 10 2012 024 560 B3 and DE 195 13 441 A1 mentioned above.

What is essential for the VLF concept of the tangent delta measurement is that a low-voltage-side earth input, referred to herein as internal earth collection point 55, and the high-voltage circuit arrangement 33 comprise a high-voltage-side output, here the test object connection 27 A, on the high-voltage side of the transformers 41, 43 . For the test, the high-voltage-side output is electrically connected to the conductor 3A (see FIG. 1) of the test object 3. During operation, the low-voltage-side earth input represents an internal earth potential and is electrically connected to the protective earth connection 27 C, wherein a measurement signal for the tangent delta diagnosis can be detected at this electrical connection. For the test by means of tangent delta diagnosis, the shield 3B (see FIG. 1) of the test object 3 is also connected to protective earth, so that the shield 3B and the VLF test device 1, in particular the test voltage generation unit 7, lie on a common protective earth potential 19. In the case of a defect in the test object 3, when the protective earth connection 27C is connected to the same earth potential (protective earth potential 19), an electrical circuit can form, through which a measurement current flow can establish and which extends from the high-voltage circuit arrangement 35 via the test object 3, in particular a defect, and through the protective earth connection 27C via the internal earth collection point 55 back to the high-voltage side of the transformers 41, 43 .

As shown in FIG. 2, the measurement current at a connecting conductor 57, which electrically connects the low-voltage-side earth input (internal earth collection point 55) to the protective earth connection 27C, is accessible within the test device 1 for a measurement and in particular advantageously in a low-voltage environment. The connecting conductor 57 can be used, for example, for a low-frequency signal tap 59, for example via an impedance, for producing a diagnostic signal. The diagnostic signal can be used in the context of an analog and/or digital signal processing in the tangent delta measurement unit 11 for determining the phase and, thus, the power loss.

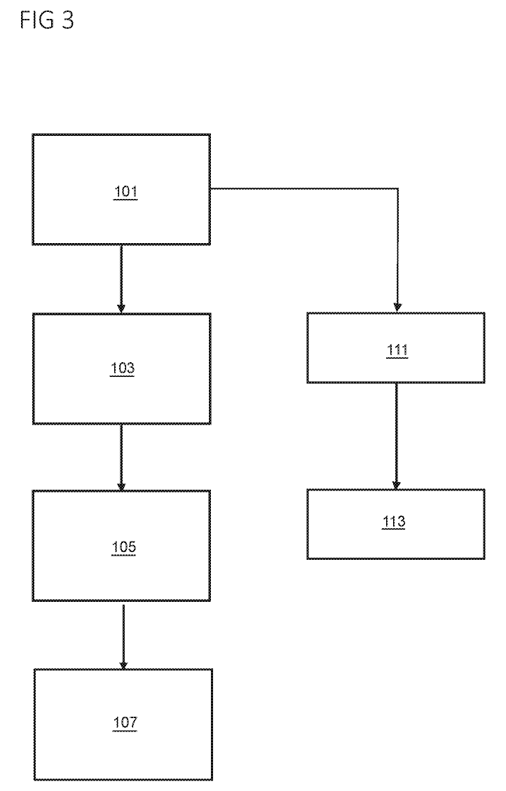

The measurement process is exemplarily summarized in connection with FIG. 3. In accordance with a method for testing a test object (e.g., the high-voltage or medium-voltage cable), a test voltage is produced using the test device 1 (step 101). A measurement current is caused in the connecting conductor 57 with the test voltage when the high-voltage or medium-voltage cable is connected (step 103). Since the connecting conductor 57 electrically connects the internal earth collection point 55 to the protective earth connection 27C, a measurement current flows through the connecting conductor 57 when the test object (e.g., the high-voltage or medium-voltage cable) is tested, said measurement current being formed due to the applied test voltage between the internal earth collection point 55 and the shield 3B of the test object/high-voltage or medium-voltage cable, said shield likewise being at protective earth potential 19. A low-frequency diagnostic signal assigned to the measurement current is produced with the low-frequency signal tap at the current collection point for, e.g., a VLF phase rotation measurement (step 105). An evaluation of the low-frequency diagnostic signal in an evaluation electronics, for example the tangent delta measurement unit 11, checks whether a fault is present in the high-voltage or medium-voltage cable (step 107).

In contrast to VLF test generators of low power, which can usually be realized with purchased potential-isolated power supply units, no potential isolation of the input voltage to the DC intermediate circuit is usually implemented in VLF test generators for higher powers/higher voltages because potential-isolated power supply units are large and cost-intensive.

The above-explained lack of potential isolation in VLF test generators for higher powers/higher voltages causes the presence of the PGND in the intermediate circuit because a connection to protective earth potential is not possible due to the rectifier on the input side. Due to the PGND reference, an output and smoothed voltage signal can have an alternating voltage component with a frequency of twice the frequency of the input alternating voltage (e.g., mains frequency) and corresponding harmonics (multiples of the mains frequency) with respect to protective earth potential. That is, for technical reasons, harmonic currents are not suppressed in non-potential-isolated setups of test generators.

In customary circuit arrangements of VLF test generators for higher powers/higher voltages, (high-voltage) transformers are furthermore used in the voltage generation path, see transformers 41, 43 in FIG. 2. Each of the transformers provides an (inductive) primary-secondary coupling for amplifying the voltages to, e.g., +10 kV or −10 kV. Without countermeasure, twice and multiples of the input frequency (starting from the incoming output alternating voltage) can now lie on the measurement current through the test object via the capacitive coupling of the transformers and, thus, influence the diagnostic signal via the current detection (current shunt). At high voltages, disturbance signals occur with — in relation to the useful signal — e.g., up to four times the amplitudes of the useful signal. With reference to FIG. 2, these parasitic currents (mains-induced disturbances) originate in the AC/DC converter of the power converter 31.

As such parasitic currents have frequencies similar to the measurement currents detected in the context of the tangent delta measurement, they can influence the measurement result. Customary (AC) power sources — such as a 50 Hz/60 Hz power supply network or a regulated generator at frequencies in the range of 40 Hz to 65 Hz — can lead to doubled frequencies in the range of 80 Hz to 130 Hz as well as the associated integer multiples, for example, up to the tenth harmonic, as parasitic currents. In other words, the resulting frequencies lie in the range of, e.g., 0.8 kHz to 1.3 kHz, for example, at 1 kHz or 1.2 kHz for the tenth harmonic. Signal sampling in the tangent delta measurement uses, for example, a sampling rate in the range of, e.g., 5 kHz to 100 kHz to detect a signal bandwidth of 5 kHz to 50 kHz, so that such source-induced disturbance signals can also be detected. In other words, the frequency range of a mains-induced disturbance signal lies within the bandwidth of the tangent delta measurement.

As explained, for the concepts described herein, the low-voltage side of the transformers is not potential-decoupled from the voltage source, so that, in principle, a ripple (harmonics of the input alternating voltage), which disturbs the measurement, can form as a parasitic current on the high-voltage side.

In VLF test generators for higher powers/higher voltages, leakage currents can furthermore arise on the high-voltage side of the transformers due to the high voltages. The background is that leakage currents can intrinsically be present in high-voltage transformers at differential voltages greater than, e.g., 1 kV. Furthermore, such leakage currents are variable, in particular temperature- and load-dependent, and, thus, represent a dynamic error variable. Their influence on, e.g., a tangent delta measurement is, thus, not predictable.

The inventors have recognized that these disturbances are not only caused by the requested power, but rather that also the power class (and, thus, the topology) of the power electronics can lead to the disturbances.

Both mains-induced parasitic currents and high-voltage-side leakage currents can, in principle, influence the tangent delta measurement (the diagnostic signal).

In the context of the double shield concept, the inventors have now implemented a concept for avoiding such an influence. Disadvantageous effects of parasitic currents and/or leakage currents can be reduced, preferably avoided, according to the invention, in that the parasitic currents and leakage currents are discharged in a targeted manner by specially configured adjustments within the transformer.

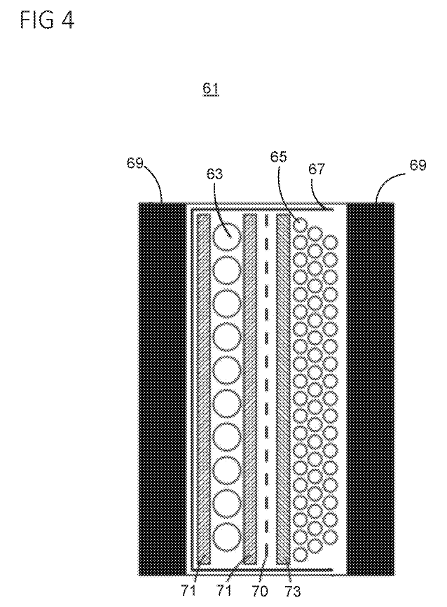

FIG. 2 shows, on the one hand, an exemplary implementation for discharging mains-induced parasitic currents and, on the other hand, two exemplary implementations for discharging leakage currents. An exemplary configuration of a transformer 61 for use according to the invention in a test device is depicted in FIG. 4, wherein the specific setup corresponds exemplarily to the transformer 41 in FIG. 2. Comparable structural components have been provided with the same reference numerals in FIGS. 2 and 4.

Generally, each of the transformers 41, 43, 61 (generally, each transformer) comprises at least one coil pair comprising a primary winding 63 and a secondary winding 65. Winding ends of the primary winding 63 are electrically connected to the HF output pair (in FIG. 2, the HF outputs 39A, 39B) and correspondingly lie, for example, at a maximum of 400 V. A first winding end of the secondary winding 65 is electrically connected to the internal earth potential (in FIG. 2, to the internal earth collection point 55) and a second winding end of the secondary winding 65 is electrically connected to the high-voltage output (in FIG. 2, to the high-voltage outputs 41A, 43A) for outputting the high-voltage signal (with voltages of, for example, more than 3 kV, e.g., up to 20 kV).

The windings are, for example, successively wound onto an annular winding body 67 (for example, made of plastic) in trapezoidal arrangements with a plurality of layers as primary or secondary coil and, e.g., cast with casting resin. The winding body 67 is used, inter alia, for mechanical stabilization during the production/winding of the coils. The winding body 67 further separates and insulates the primary coil from the core. In FIG. 4, the winding body 67 is illustrated with a U-shaped cross-section. Distance values between the coils lie at, e.g., a few millimeters at a plurality of 10 kV voltage differences.

In the example of FIG. 4, the arrangement of primary winding 63 and secondary winding 65 is delimited radially by a transformer core 69. The transformer core 69 simplifies the generation of a plurality of kilovolts of secondary voltage. The transformer core 69 is configured, for example, as a ferrite core with two half shells.

An insulating film 70, for example, a polyethylene terephthalate film or a film consisting of polycondensed aromatic dianhydride and aromatic diamine, is arranged between the primary winding 63 and the secondary winding 65 for electrical insulation. In particular in an implementation of the double shield concept according to the invention, the insulating film 70 is used for low-voltage insulation.

The double shield concept uses, on the one hand, a protective earth shield 71. The protective earth shield 71 is configured for shielding the primary winding 63 and surrounds the latter circumferentially, but in particular without forming a short-circuit winding. The protective earth shield 71 is capacitively coupled to the primary winding 63 and is electrically connected to the protective earth potential 19. The protective earth shield 71 is used to discharge a parasitic current caused by the harmonics to the protective earth potential 19.

The double shield concept uses, on the other hand, an internal earth shield 73. The internal earth shield 73 is configured for shielding the secondary winding. For this purpose, the internal earth shield 73 is capacitively coupled to the secondary winding 65 and is electrically connected to the internal earth collection point 55. The internal earth shield 73 is used to receive leakage currents, here e.g. an HF high-voltage leakage current produced in the transformer, and to discharge them to internal earth potential, in the setup of FIG. 2 to the internal earth collection point 55.

The protective earth shield 71 and/or the internal earth shield 73 are each configured, for example, as a circumferential copper strip (generally made of a highly conductive material), wherein in particular no short-circuit winding is formed.

In general, a compact setup is more efficient, so that the degree of filling of the transformer is to be kept high. In an embodiment shown in FIG. 4 and indicated schematically in FIG. 2 for the transformer 41, the internal earth shield 73 is partially realized by the transformer core 69. Thereby it is possible to keep the setup of the HV transformers compact while maintaining the insulation paths. As the primary winding 63 is surrounded by the protective earth shield 71, there is no “power-ground coupling” from the primary side to the core. Furthermore, there is usually only a voltage difference of a few volts (e.g., 5 V) between the protective earth shield 71 and the internal earth shield 73, so that the requirements on the insulating film 70 with regard to the insulation are reduced.

Alternatively, as indicated for the transformer 43 in FIG. 2, there can be provided an internal earth shield that completely surrounds the secondary coil (circumferentially, but forming no short-circuit winding). The introduction of a shield winding configured in such a manner can require the maintenance of a corresponding insulation distance as well as a voltage-resistant bushing of the high-voltage outputs 41A, 43A (see FIG. 2) and, thus, a spatially larger setup.

Based on the double shield concept, information with respect to a quality of a given transformer insulation can be obtained during the operation of the test device 1, in particular continuously during a tangent delta measurement. In particular, a structural fault of an insulation of the transformer can be detected in this manner. For this purpose, a signal tap, for example, a leakage current measurement impedance 75 in FIG. 2, can be provided that electrically connects the internal earth shield 73 of the secondary winding 65 of the transformer to the internal earth collection point 55. With, e.g., the leakage current measurement impedance 75, a leakage current in the transformer can be continuously detected and evaluated. The evaluation comprises, for example, a plausibility test or a temporal development of the detected leakage currents.

FIG. 3 illustrates, in addition to the test method of a test object, a method for testing a transformer arranged in a test device, in which an internal earth shield of a secondary winding of the transformer is electrically connected to an internal earth collection point of the test device via a signal tap (e.g., leakage current measurement resistor or a capacitive coupling). A test voltage is produced with the test device for the test (step 101). E.g., a leakage current is measured with the leakage current measurement resistor (step 111). The leakage current is evaluated in evaluation electronics of the test device with regard to an insulation damage of the transformer (step 113).

FIGS. 5 to 8 illustrate the effects of the use of a double shield concept according to the invention. If transformers with a double shield structure are used in a test device, parasitic currents can be largely suppressed or returned to the source. The quality of the measurement could be substantially improved in this manner, in particular for high voltages. To illustrate that the effects addressed by the double shield, as described above, can be shown as a disturbance in the measurement current and diagnostic signal, the current was additionally analyzed with an oscilloscope in a measurement at the current shunt (measurement resistor/signal 59), respectively for the case of a transformer without and with a double shield structure.

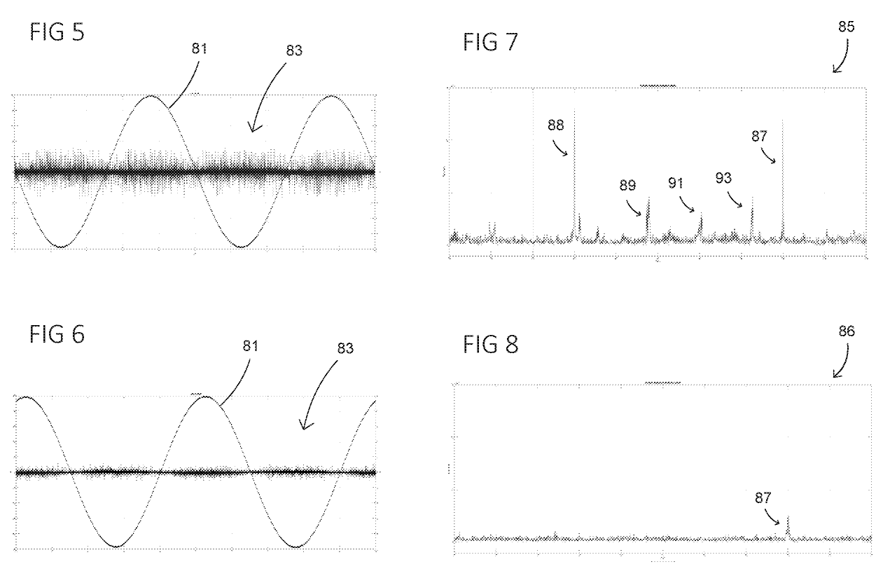

FIGS. 5 and 6 show the temporal course of the applied voltage 81 detected with an oscilloscope and the associated temporal high-frequency course of detected measurement currents 83. Without using the double shield concept, parasitic currents of up to 40 μA can be seen. When using the double shield concept for the transformer, the parasitic currents are reduced significantly down to a few μA.

In the spectra 85 and 86 shown in FIGS. 7 and 8, the 0.1 Hz test frequency, which is used for VLF testing and diagnosis, can be seen as the dominant frequency 87. The second- and third-highest frequencies 88, 89 in the spectrum 85 lie in FIG. 7 (i.e., without using the double shield concept) at 50 Hz or 100 Hz (fundamental and harmonic) and represent the disturbances caused by the mains voltage at 50 Hz and coupled to the measurement current. Due to the double shielding of the primary and secondary windings of the transformer, FIG. 9 no longer shows these frequencies in the spectrum 86 when the double shield concept is used.

As can furthermore be seen, the double shield concept can also additionally reduce parasitic frequencies 91 and 93 (see spectrum 85), which can be produced, e.g., by other mains loads.

The features of the methods and devices used in the present description, which have been referred to as “unit”, “device” or the like, can be implemented, e.g., as discrete physical units, as conceptual functional units, e.g., as software code (in the context of an evaluation program), which is stored in a memory unit (memory), routines by a microprocessor and/or within a hybrid hardware/firmware structure in the context of the knowledge of the person skilled in the art. Furthermore, two or more “units” etc. can be integrated together in a single physical circuit structure (e.g., an integrated unit or structure). For example, a processor can be controlled by programming code (stored instructions), wherein the programming code is able to perform the respective functions when it is executed by a processor, such as, for example, a microprocessor.

The features mentioned in particular in the claims can, thus, be configured as software, hardware and/or a combination of hardware and software. Specific details of the individual units are described in the description (and in particular in the exemplary sections). This provides a person skilled in the art with sufficient information to implement the corresponding structures in hardware circuits or software code. By way of example, the “evaluation unit” disclosed herein can be embodied in the structure of a central processing unit (CPU) that is configured with instructions for carrying out the operations for deriving fundamental oscillation information. The CPU can comprise one or more microprocessors in connection with one or more memory elements. A memory element can store one or more microprocessor-readable instructions (programs) that, when executed by the microprocessor, perform, for example, the Fourier or wavelet transformation. Furthermore, the measurement and evaluation unit 9 and the control can comprise various units that interact with one another in order to perform the desired actions such as receiving, accessing and/or sending data sets, identifying maxima, etc.

It is explicitly emphasized that all features disclosed in the description and/or the claims are to be regarded as separate and independent of one another for the purpose of the original disclosure as well as for the purpose of limiting the claimed invention independently of the combinations of features in the embodiments and/or the claims. It is explicitly stated that all range indications or indications of groups of units disclose any possible intermediate value or subgroup of units for the purpose of the original disclosure as well as for the purpose of limiting the claimed invention, in particular also as a limit of a range indication.

What is claimed is:

1. A test device for testing a test object, in particular a high-voltage or medium-voltage cable, with a test method using a very low-frequency (VLF) test voltage, comprising:
a power converter, wherein the power converter comprises:
an alternating voltage input for receiving an input alternating voltage with respect to a protective earth potential,
a low-voltage circuit arrangement comprising a rectifier circuit and at least one switching power supply, wherein the low-voltage circuit arrangement is configured to generate an HF signal with respect to a floating reference potential from the input alternating voltage, and
at least one HF output pair for outputting the HF signal and the floating reference potential;
a transformer for transforming the HF signal into a high-voltage signal, wherein the transformer comprises:
a primary winding, the winding ends of which are electrically connected to the HF output pair,
a protective earth shield for shielding the primary winding, wherein the protective earth shield is capacitively coupled to the primary winding and is electrically connected to the protective earth potential,
a secondary winding, the first winding end of which is electrically connected to an internal earth collection point and the second winding end of which is electrically connected to a high-voltage output for outputting the high-voltage signal, and
an internal earth shield for shielding the secondary winding, wherein the internal earth shield is capacitively coupled to the secondary winding and is electrically connected to the internal earth collection point;
a rectifier circuit electrically connected to the high-voltage output for outputting a rectified high-voltage signal; and
a high-voltage circuit arrangement for generating the VLF test voltage based on the rectified high-voltage signal.

2. The test device of claim 1, wherein an intermediate circuit for generating a direct voltage with respect to the floating reference potential is formed in the low-voltage circuit arrangement, wherein the direct voltage is subjected to harmonics depending on the received input alternating voltage, and the protective earth shield capacitively coupled to the primary winding is configured to discharge a parasitic current caused by the harmonics to the protective earth potential.

3. The test device of claim 1, wherein the internal earth shield capacitively coupled to the secondary winding is configured to discharge an HF high-voltage leakage current produced in the transformer to the internal earth collection point.

4. The test device of claim 1, wherein the transformer further comprises a transformer core, which is configured as part of the internal earth shield capacitively coupled to the secondary winding and which is electrically connected to the internal earth collection point.

5. The test device of claim 1, wherein:
the transformer further comprises a winding body, in particular U-shaped in cross-section, on which a primary winding is arranged embedded in the protective earth shield, an insulating film, the internal earth shield and the secondary winding, and wherein the winding body is arranged in particular between sections of a core of the transformer, and/or
wherein the primary winding is delimited radially on both sides by the protective earth shield and/or the secondary winding is delimited radially on both sides by the internal earth shield.

6. The test device of claim 1, wherein the transformer and the rectifier circuit form a high-voltage source and the high-voltage circuit arrangement comprises at least one semiconductor switch cascade and at least one amplifier, which are assigned to the transformer.

7. The test device of claim 1, wherein:
the low-voltage circuit arrangement comprises two switching power supplies, which are configured such that a positive and a negative HF signal are output at corresponding HF output pairs;
the test device comprises two transformers, each comprising a protective earth shield and an internal earth shield, for transforming the positive and the negative HF signal into a positive and a negative high-voltage signal and two rectifier circuits electrically connected to high-voltage outputs of the transformers for outputting a rectified positive and a rectified negative high-voltage signal; and
wherein the high-voltage circuit arrangement is configured for generating the VLF test voltage based on the positive rectified high-voltage signal and the negative rectified high-voltage signal.

8. The test device of claim 1, wherein the high-voltage circuit arrangement comprises a test object connection for connecting a high-voltage-side output of the high-voltage circuit arrangement to a conductor of the test object, in particular via a measurement connection cable.

9. The test device of claim 1 further comprising:
a protective earth connection;
a connecting conductor, which electrically connects the internal earth collection point to the protective earth connection, so that a measurement current flows through the connecting conductor when the test object is tested, said measurement current being formed between the internal earth collection point and a shield of the test object, said shield likewise being at protective earth potential;
a low-frequency signal tap at the current collection point, at which a low-frequency diagnostic signal is produced based on the measurement current; and
evaluation electronics, which are connected to the low-frequency signal tap for receiving the low-frequency diagnostic signal and which are configured for a VLF phase rotation measurement.

10. The test device of claim 9, wherein:
the low-frequency signal tap is configured to detect an instantaneous value of a current strength in the connecting conductor, and/or comprises an impedance in the connecting conductor, in particular a parallel circuit of resistor and capacitor; and/or
the evaluation electronics are configured to determine a loss factor assigned to the test object from the diagnostic signal, and in particular are configured for detecting low frequencies of the diagnostic signal in the range of 0.01 Hz to 1 Hz with a sampling rate with frequencies in the range of, in particular, 5 kHz to 100 kHz; and/or
the evaluation electronics comprise at least one analog and/or digital signal processing unit and/or a processor and/or a buffer memory.

11. The test device of claim 1 further comprising a signal tap, in particular a leakage current measurement impedance or a leakage current measurement resistor, which electrically connects the internal earth shield of the secondary winding of the transformer to the internal earth collection point and is provided for detecting a structural fault of an insulation of the transformer.

12. A method for testing a test object, in particular a high-voltage or medium-voltage cable, using the test device of claim 1 comprising the steps:
producing a test voltage with the test device;
causing a measurement current with the test voltage when the test object is connected in a connecting conductor, which electrically connects an internal earth collection point of the test device to a protective earth connection of the test device, so that the measurement current flows through the connecting conductor when the high-voltage or medium-voltage cable is tested, said measurement current being formed between the internal earth collection point and a shield of the test object, said shield likewise being at protective earth potential;
producing a low-frequency diagnostic signal assigned to the measurement current for a VLF phase rotation measurement with a low-frequency signal tap on the connecting conductor; and
evaluating the low-frequency diagnostic signal in evaluation electronics with regard to a fault in the high-voltage or medium-voltage cable.

13. The method of claim 12, wherein:
a parasitic current caused by harmonics of a received input alternating voltage is discharged to the protective earth potential via a protective earth shield; and/or
a leakage current produced in the transformer is discharged to the internal earth collection point via an internal earth shield of the transformer.

14. A method for testing a transformer arranged in the test device of claim 1, wherein an internal earth shield of the secondary winding of the transformer is electrically connected to an internal earth collection point of the test device via a leakage current measurement impedance, comprising the steps:
Producing a test voltage with the test device;
measuring a leakage current with the leakage current measurement impedance; and
evaluating the leakage current in evaluation electronics of the test device with regard to an insulation damage of the transformer.
